(19) United States
(12) Patent Application Publication
(10) Pub. No.: US 2026/0079311 A1
(43) Pub. Date: Mar. 19, 2026

(54) SYSTEM AND METHOD FOR AN EXTENDED BURIED OXIDE LAYER FOR SILICON PHOTONIC INTEGRATED CIRCUITS

(71) Applicant: MIXX TECHNOLOGIES, INC., San Jose, CA (US)

(72) Inventors: Rebecca Kayla Schaevitz, Sunnyvale, CA (US); Vivek Raghuraman, San Jose, CA (US)

(73) Assignee: MIXX TECHNOLOGIES, INC., San Jose, CA (US)

(21) Appl. No.: 19/333,147

(22) Filed: Sep. 18, 2025

Related U.S. Application Data
(60) Provisional application No. 63/696,045, filed on Sep. 18, 2024.

(51) Int. Cl. G02B 6/42; H01L 21/302; H01L 21/768; H01L 23/00; H01L 23/522; H01L 25/18

(52) U.S. Cl. CPC G02B 6/4214; G02B 6/4206; H10W 20/023; H10W 20/42; H10W 90/00; H10P 50/00; H10W 80/312; H10W 80/327; H10W 90/794

(57) ABSTRACT

A device and method of manufacturing a semiconductor device with integrated photonic and electronic components is described. The method may include: providing a silicon-on-insulator (SOI) wafer having a silicon handle wafer, a buried oxide (BOX) layer, and a silicon waveguide layer; forming a photonic integrated circuit (PIC) including one or more of the waveguide or a metal layer; removing the silicon wafer to expose the BOX layer; and extending the BOX layer by one or more of: depositing oxide and planarizing onto the BOX layer to increase BOX layer thickness to an extended BOX layer, or fusion bonding a second wafer with a surface oxide layer. The device may include a photonic integrated circuit (PIC), an additional oxide layer, and an integrated optical component positioned to reflect or reshape optical signals within a waveguide layer vertically.

### RELATED APPLICATION

This application claims the benefit of U.S. Provisional Application No. 63/696,045, filed Sep. 18, 2024, the disclosure of which is incorporated herein by reference in its entirety for all purposes.

### BACKGROUND

Unless otherwise indicated herein, the materials described herein are not prior art to the claims in the present application and are not admitted to be prior art by inclusion in this section.

The integration of photonic and electronic components in semiconductor devices has become increasingly used for modern applications such as high-performance computing, artificial intelligence, data center communication, and telecommunications. Optical data transmission offers significant advantages over traditional electrical interconnects, including higher bandwidth, higher density and longer reach. However, the integration of photonic circuits with electronic integrated circuits (EICs) in a compact, scalable package remains a significant challenge due to limitations in backend manufacturing processes.

The subject matter claimed in the present disclosure is not limited to embodiments that solve any disadvantages or that operate only in environments such as those described above. Rather, this background is only provided to illustrate one example technology area where some embodiments described in the present disclosure may be practiced.

### SUMMARY

The embodiments described herein relate generally to wafer-to-wafer hybrid bonding process that enables enhanced optical mode sizes in silicon photonic designs. Additionally, the embodiments described herein enable the integration of photonic and electronic circuits with the enhanced optical mode sizes. In some embodiments, by incorporating an additional oxide layer during the backend process, the embodiments herein allow for greater flexibility in the design of the optical waveguide and optical mode size, significantly reducing alignment requirements and improving optical coupling efficiency. In some embodiments, the process of incorporating the additional oxide layer may also enable the insertion of a turning element to allow for surface coupling of light, thereby enabling an increased density of light paths compared to the linear edge. The embodiments herein provide a scalable solution for integrating photonic and electronic components in high-performance semiconductor packages.

The objects and advantages of the embodiments will be realized and achieved at least by the elements, features, and combinations particularly pointed out in the claims. Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is noted, however, that the appended drawings illustrate only some aspects of this disclosure and the disclosure may admit to other equally effective embodiments.

To facilitate understanding, identical reference numerals have been used, where possible, to designate identical elements that are common to the figures. It is contemplated that elements and features of one embodiment may be beneficially incorporated in other embodiments without further recitation.

FIGS. 1A-1C illustrates a schematic of an exemplary method for fabricating a semiconductor device, in accordance with some embodiments;

FIGS. 2A-2D illustrate schematics of exemplary method for fabricating an integrated circuit having a silicon-photonic bridge, in accordance with some embodiments;

FIG. 3 illustrates an exemplary integrated circuit having a silicon-photonic bridge, in accordance with some embodiments; and

FIGS. 4A-4F illustrate schematics of an exemplary method for fabricating an integrated circuit having a silicon-photonic bridge, in accordance with some embodiments.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the desired performance and outcomes as described in one or more embodiments herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Embodiments described as being implemented in hardware should not be limited thereto, but can include embodiments implemented in software, or combinations of software and hardware, and vice-versa, as will be apparent to those skilled in the art, unless otherwise specified herein. In the exemplary embodiments described herein, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In some semiconductor packaging processes, photonic integrated circuits (PICs) may be fabricated using silicon-on-insulator (SOI) wafers. These wafers may include a buried oxide (BOX) layer that separates the silicon waveguide from the bulk silicon substrate. The BOX layer may aid in confining the optical mode within the waveguide. However, in SOI wafers used for PICs, the BOX layer may be limited to a thickness of approximately 2-3 microns, particularly in larger wafers, such as 300 mm. Such BOX layer thicknesses may restrict the size of the optical mode that may be supported, as larger modes may leak into the silicon substrate, leading to significant optical losses.

As a result, the confined optical mode in conventional packaging systems may use precise alignment between photonic components and the external optical interfaces (such as fiber optics), often also using further components to mode convert from the smaller PIC mode to the larger fiber mode. Such tight alignment tolerance may increase the complexity of the manufacturing process, reducing yield and increasing the cost of production. The small optical mode size may limit the efficiency of optical coupling, leading to higher insertion losses and reduced overall performance of the device. Alternatively, to drive the mode larger off the PIC, some designs may use an undercut of the silicon handle wafer to avoid optical leakage, leaving a diving board type structure exposed. This undercut may lead to lower yields during manufacturing due to the fragility of the structure in addition to using materials, such as low refractive index epoxies, to confine the optical mode. These options may lead to complexity in the manufacturability of the final design to get light off the PIC and into a fiber. Modification of the BOX layer has not yet been enabled due to overall PIC integration and packaging designs.

The embodiments herein introduce an advanced wafer-to-wafer hybrid bonding process for extending a buried oxide layer to a photonic integrated circuit (PIC) as well as integrating photonic and electronic components within a semiconductor package, addressing the limitations of existing backend packaging techniques. The embodiments described below allow for seamless integration of photonic integrated circuits (PICs) and electronic integrated circuits (EICs) while providing greater flexibility in terms of optical mode size and alignment tolerances, thereby improving overall performance and manufacturing yield.

For example, in some embodiments, a wafer-to-wafer bonding process begins with a silicon photonic wafer that includes an initial BOX layer, waveguides, and nitride layers, as provided by a foundry. In some embodiments, the wafer undergoes an advantageous operation where the handle wafer is removed, and a new handle wafer, including an oxide layer of 1 to 10 microns in thickness on top of silicon, is introduced. This new oxide layer, which may be customized to various thicknesses, allows for the expansion of the optical mode beyond the limitations of the original BOX layer. As a result, larger optical modes may be supported, enabling looser alignment tolerances and reducing optical coupling loss.

In some embodiments, a wafer-to-wafer bonding process may also involve the creation of through-silicon vias (TSVs) and through-dielectric vias (TDVs) that extend through the oxide and silicon layers and connect the backend metal stack to external components for power, ground and signal. Wafer-to-wafer hybrid bonding may be used to align and connect the TSVs and TDVs, ensuring precise electrical connections. In some embodiments, once the bonding is complete, a backside thinning operation may be performed to expose and metallize the TSVs for microbumping or similar, creating a fully interconnected structure.

Moreover, in some embodiments, trenches may be etched to accommodate optical components, such as mirrors or lenses, which may direct optical signals on and off the PIC. Such trenches, along with conformal oxide coating and thinning processes, may ensure that the structure remains planar for future wafer-based processes and that components are aligned for optimal performance. In some embodiments, the wafer-to-wafer or die-to-wafer bonding process may conclude with the integration of the EIC and a silicon bridge, which may electrically connect the photonic and electronic circuits to a co-packaged ASIC.

As described in detail below, the embodiments herein facilitate the capability to expand the optical mode size by introducing an additional oxide layer, allowing for improved optical coupling and reduced alignment requirements. This enhanced flexibility in backend packaging may enable higher manufacturing yields and better performance of integrated photonic and electronic systems. The process may be scalable and compatible with existing foundry and backend manufacturing workflows, making it a practical solution for next-generation semiconductor devices.

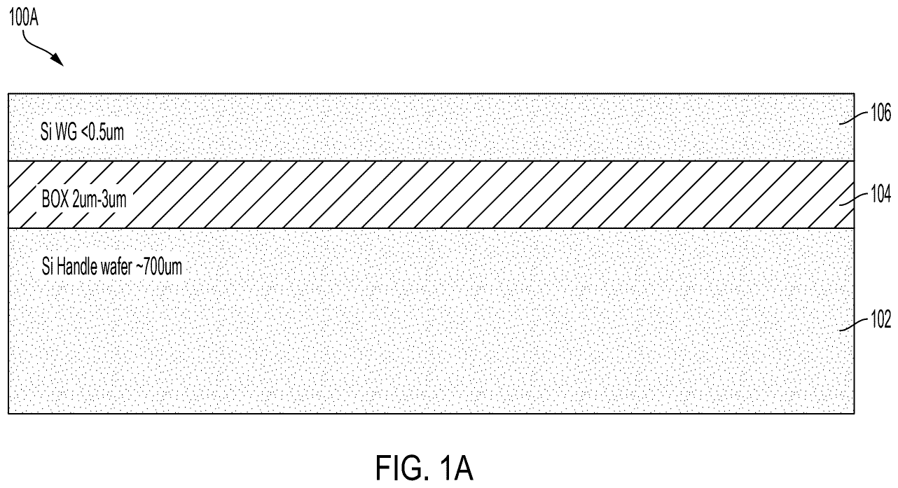

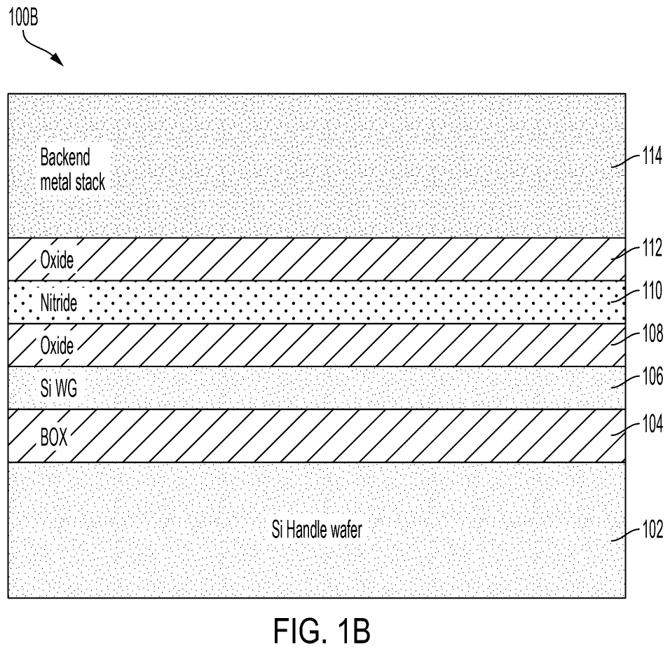

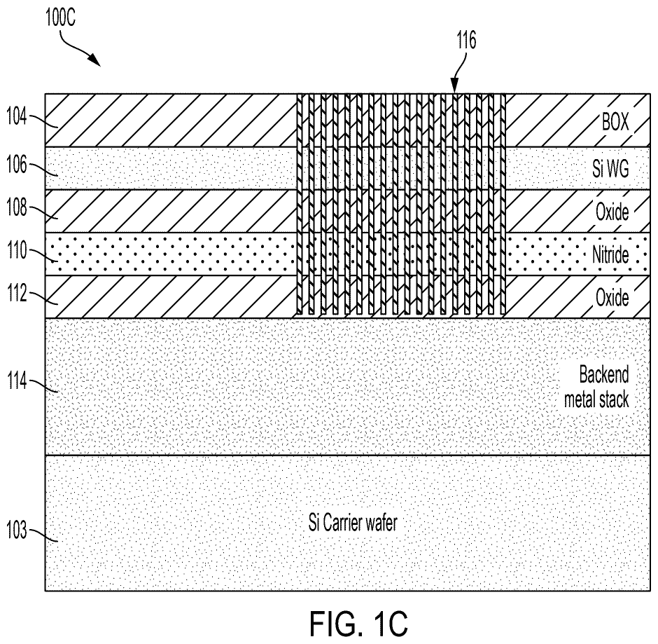

FIGS. 1A-1C depict a formation process for a starting silicon on insulator (SOI) 100A, 100B, 100C. As shown in FIG. 1A, a starting SOI 100A may include a silicon handle wafer 102, a BOX layer 104 and a silicon waveguide 106. The initial stage of the silicon-on-insulator (SOI) wafer build process may begin with a silicon photonic wafer (e.g., 100A) provided by the foundry or wafer supplier. The SOI wafer may serve as the foundational substrate upon which the subsequent photonic and electronic components may be built.

As shown in FIG. 1A, in some embodiments, silicon handle wafer 102 may include approximately 700 microns in thickness. Such thick silicon layer may act as the mechanical support for the rest of the wafer stack during the various processing operations, providing structural integrity. The silicon handle wafer may remain in place until it is later removed during the manufacturing process to accommodate the introduction of additional layers and components. On top of silicon handle wafer 102 may lie BOX layer 104. BOX layer 104 may be 2-3 microns thick for 300 mm wafers. BOX layer 104 may be an advantageous dielectric component of the SOI wafer, serving as an electrical insulator between the silicon handle and the active silicon layers above BOX layer 104. BOX layer 104 may play an advantageous role in the performance of the photonic circuits, as BOX layer 104 may help to confine the optical mode within the waveguides and prevent the optical signal from leaking into the underlying silicon handle.

The thickness of BOX layer 104 may aid in controlling the optical characteristics of the waveguide. In some SOI wafers, the BOX layer's thickness may be limited to a 2-3 micron range, and the thickness may trend towards the lower end (around 2 microns) in larger wafers, such as the 300 mm wafers, for example. Yet, such limitation in thickness may restrict the size of the optical mode that may propagate within the waveguides. Optical modes that are too large may extend beyond the confines of the BOX layer and into the silicon handle, leading to optical losses and degraded performance.

As shown in FIG. 1A, on top of BOX layer 104 may be the silicon waveguide (Si WG), which may be less than 0.3 to 0.5 microns in thickness. The Si WG layer 106 may be the active layer used to guide optical signals within the photonic circuits. The precise thickness of the waveguide may control the effective index of the waveguide and ensure efficient optical signal propagation. Si WG layer 106 may be responsible for confining the light within the photonic circuit, with the BOX layer 104 beneath Si WG layer 106 helping to reflect and contain the optical mode.

The thickness of the Si WG layer 106 may be tightly controlled, as a variation in thickness may impact the effective index and, therefore, the ability to confine light within the waveguide. The capability to confine light may be advantageous when integrating photonic circuits in a small area, as maintaining the integrity of the optical signal throughout the circuit may be used for high-performance applications such as data transmission, telecommunications, and high-speed computing.

Referring now to FIG. 1B, once the SOI 100A is provided to the foundry, additional layers may be built up to complete the photonic structure - often through topside depositions but sometimes may be flipped and enabled through backside depositions or bonding as well for some of the layers like nitride that may be challenging to integrate. As shown in FIG. 1B, in some embodiments, the foundry may deposit another oxide layer 108 followed by a nitride layer 110, and another oxide layer 112, and a series of backend metal layers 114 that are stacked on top of the photonic structure 100B. The layers (e.g., layers 104-114) may serve a specific function within the photonic integrated circuit (PIC), with the oxide layers acting as dielectric barriers, the nitride and/or silicon layers as waveguides, and the metal layers serving as electrical interconnects for signal routing and power distribution.

Photonic structure 100B may be created through a series of standard semiconductor processes, such as lithography, etching, and deposition. These processes pattern the various layers to form the photonic and electronic elements. The waveguides may be carefully defined within the silicon waveguide layer to guide light through the circuit, while the metal layers provide the electrical connections used for interfacing with electronic components.

Referring now to FIG. 1C, once the photonic IC layers (e.g., layers 104-114) are built up, in some embodiments, photonic structure 100C may be derived by flipping the PIC (e.g., 100B) upside down onto a Si Carrier wafer 103 and removing the original silicon handle wafer 102. This operation may be advantageous for preparing the PIC for subsequent backend processes, where the electrical and optical connections are made. The removal of silicon handle wafer 102 may expose the BOX layer 104 and Si waveguide layer 106, enabling the integration of additional components, such as through-dielectric vias (TDVs) 116 and/or other interconnects. The silicon handle wafer may not be used for mechanical support with the temporarily bonded Si Carrier wafer 103 now fulfilling that purpose. Exposure of the BOX layer 104 may allow for more advanced processing, such as creating vias that connect the metal stack to external components or further integration layers.

As shown in FIG. 1C, once the PIC is flipped and the silicon handle wafer 102 is removed, through-dielectric vias (TDVs) 116 may be formed or exposed if previously integrated. These vias may be advantageous for routing electrical signals through the dielectric layers (such as oxide) to connect the backend metal stack 114 with the external components or subsequent processing layers. Unlike through-silicon vias (TSVs), which extend through silicon layers, TDVs may pass through dielectric materials such as oxide. The alignment of these vias with the metal stack may be advantageous for ensuring signal integrity and efficient routing.

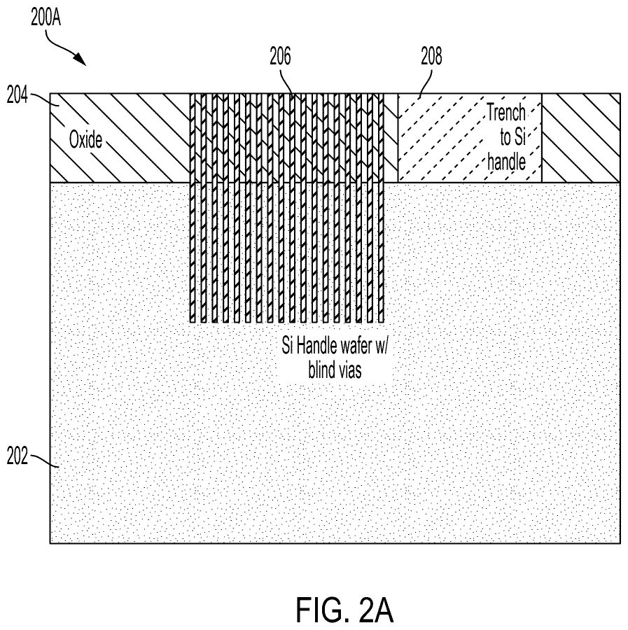

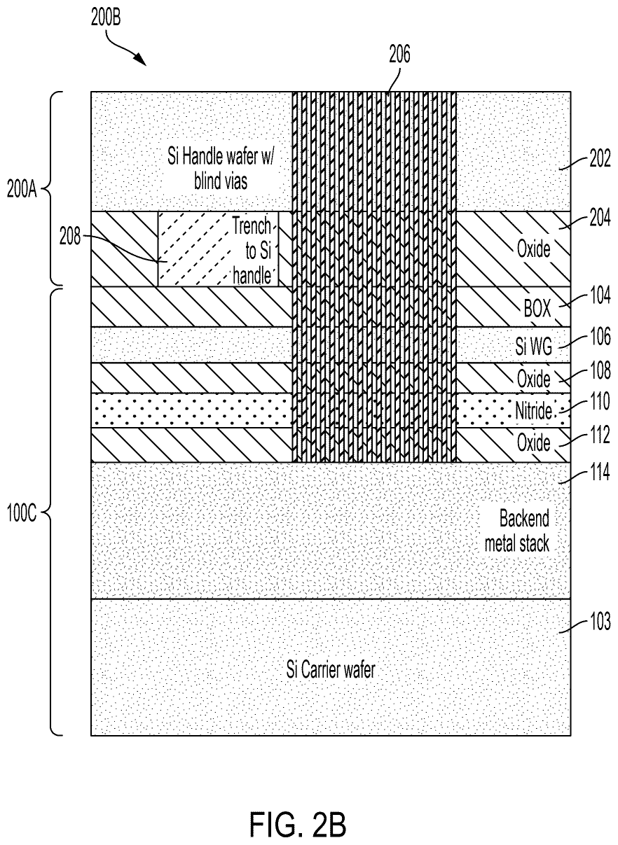

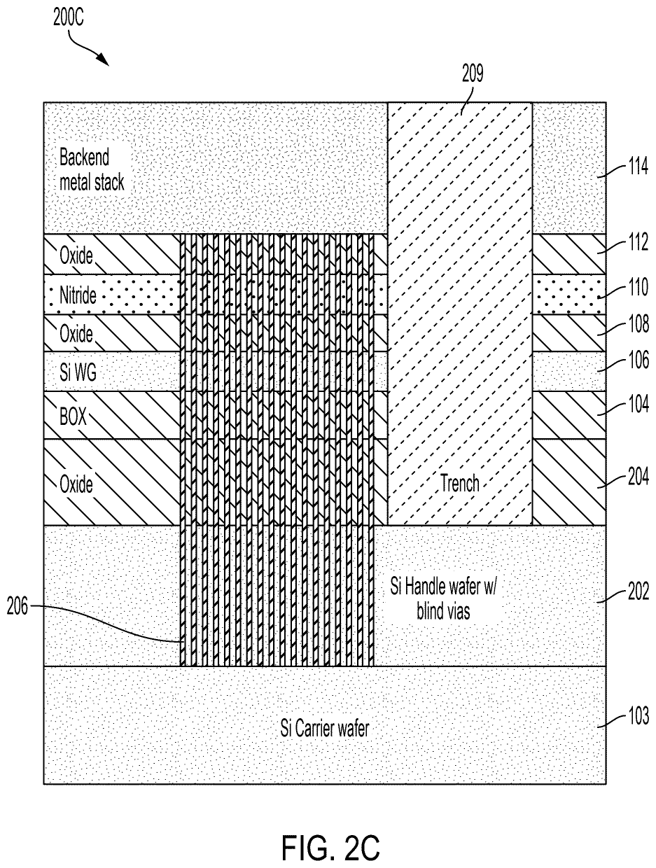

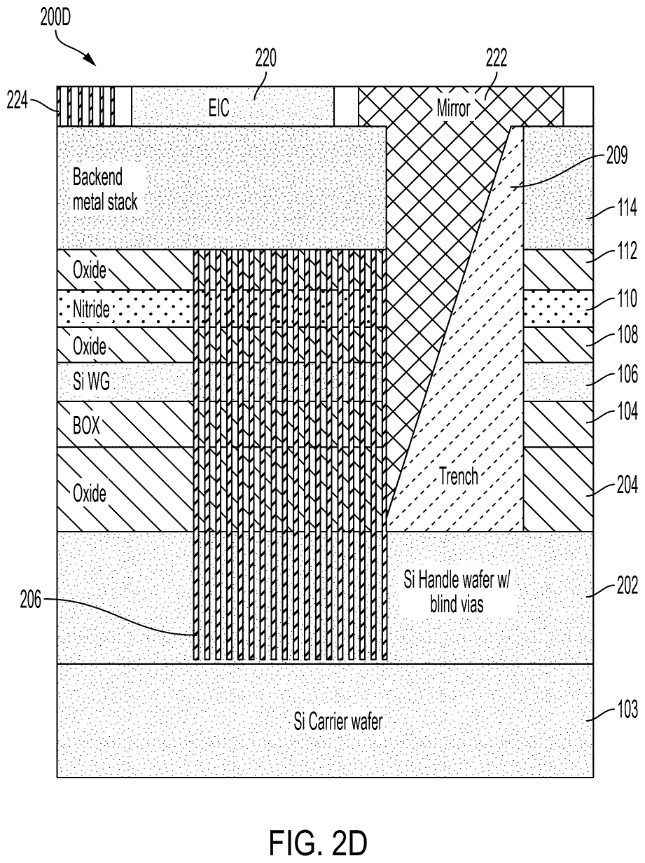

Referring now to FIG. 2A-2D in conjunction with FIGS. 1A-1C, FIGS. 2A-2D depict photonic structure 200A-200D, respectively. Photonic structures 200A-200D depict operations in a wafer-to-wafer and die-to-wafer hybrid bonding process. The use of TDVs, blind vias, trenches, lenses and mirrors, and EIC, may create a high-performance semiconductor device capable of processing both electrical and optical signals. The flexibility in mode size and the reduced alignment tolerances may make the embodiments described herein well-suited for next-generation photonic devices.

As mentioned above, a limitation in traditional SOI wafers may be the thickness of the BOX layer 104. With a thickness of 2-3 microns, BOX layer 104 may restrict the optical mode size. For clarity, a brief review follows:

Optical mode size may refer to the spatial distribution or cross-sectional area of light (or electromagnetic energy) as light propagates through a waveguide or optical fiber. More precisely, optical mode size may represent the extent to which light is confined within the core of the waveguide, determining how much of the light energy is concentrated in the core versus how much spreads into the surrounding cladding or substrate.

The optical mode size may be characterized by the mode field diameter (MFD), which may define the effective width of the optical mode. This measurement may describe the distance across the area where the optical power is most concentrated, usually taken at the points where the intensity falls to 1/e²(˜13.5%) of its maximum value. The degree to which light is confined in a waveguide may depend on various factors, such as the refractive index difference between the waveguide core and the surrounding cladding. Higher refractive index contrasts may tend to confine light more tightly, resulting in smaller mode sizes. The BOX (buried oxide) layer or an oxide layer in silicon photonics may help prevent light from leaking into the substrate, ensuring the light is well confined in the waveguide. If the light leaks beyond the waveguide (because the mode size exceeds the waveguide dimensions), optical loss may increase.

Optical mode size may also determine whether a waveguide supports single-mode or multimode propagation. In single-mode operation, one mode of light may propagate through the waveguide, while in multimode operation, multiple modes of different wavelengths or frequencies may propagate simultaneously. For single-mode systems, the optical mode may fit within the waveguide dimensions, having precise control over the mode size.

The mode size may be influenced by the waveguide's physical dimensions. For smaller waveguides, such as silicon photonic waveguides, the mode size may be carefully controlled to avoid optical losses. If the mode size is larger than the waveguide or BOX layer, light may leak into surrounding areas, reducing efficiency. The mode size may play a significant role in coupling light between different components, such as from a waveguide to an optical fiber or from one waveguide to another. A mismatch in mode size between two components may lead to coupling losses, where a significant portion of the optical signal may be lost during transmission. For example, in the case of coupling light from a photonic integrated circuit (PIC) to an optical fiber, the mode size of the PIC's waveguide may match the mode size of the optical fiber to minimize loss.

The size of the optical mode may impact the alignment tolerances during manufacturing and packaging. A smaller mode size may use higher precision in aligning waveguides or fibers for efficient signal transmission. Conversely, a larger mode size may allow for looser alignment tolerances, simplifying the manufacturing process and improving yield. The waveguide design and the material properties, including the refractive index contrast and the thickness of the core and cladding layers, may directly affect the optical mode size. For instance, a thicker oxide layer beneath the waveguide (as seen in buried oxide layers) may support a larger optical mode, allowing the light to be better confined within the waveguide.

Managing the optical mode size may be advantageous to minimize optical losses in waveguides. If the mode size is not properly confined, light may leak out, leading to scattering, reflection, or absorption losses in surrounding materials, thereby reducing the overall efficiency of the photonic device. In the context of silicon photonics and photonic integrated circuits (PICs), controlling the optical mode size may be a design consideration. In SOI wafers used for PICs, the BOX layer may help prevent light from leaking into the silicon substrate. However, the thickness of the BOX layer may limit the size of the optical mode that can propagate through the waveguide. As discussed above, a BOX layer in SOI wafers may be 2-3 microns thick, limiting the optical mode to 4-6 microns to avoid light leakage. Increasing the optical mode size (through design changes like adding a thicker oxide layer) may allow for looser alignment tolerances during coupling and packaging. This may simplify manufacturing, improve coupling efficiency, and result in higher yields and lower optical losses.

For example, if the optical mode exceeds the size supported by the BOX layer, the signal may leak into the silicon handle wafer, leading to significant optical losses and decreased performance. Accordingly, the embodiments described herein may introduce a new oxide layer during later stages of the process flow, which addresses optical mode restriction by expanding the effective BOX layer thickness. Such additional oxide layer may allow for larger optical modes to be supported, reducing the need for precise alignment during manufacturing and packaging. The increased mode size may not only improve optical coupling efficiency but also simplify the overall manufacturing process by loosening alignment tolerances, thereby enhancing yield and reducing costs.

Thus, as shown in FIG. 2A, in some embodiments, a hybrid wafer-to-wafer bonding process used for integrating photonic and electronic components within a semiconductor device may bond photonic structure 100C with a newly formed wafer with oxide and blind vias. Wafer 200A may include an oxide layer 204 on a separate Si handle wafer 202. Thus, wafer 200A may include an oxide layer 204, a silicon handle wafer 202 having blind vias 206, and, optionally, a trench to Si handle 208. As shown in FIG. 2B, wafer 200A and photonic structure 100C may be hybrid bonded with one another utilizing Si handle wafer 202 w/blind vias 206 and silicon carrier wafer 103.

In FIG. 2A, the structure may include a silicon handle wafer 202, which may be around 700 microns in thickness. Above the silicon handle wafer may be an oxide layer 204, which may serve as an insulating layer to separate the silicon handle from the rest of the semiconductor stack. The oxide layer in this case may be approximately 5 microns thick, though it may range from less than 1 to 10 microns or more depending on the specific design.

In some embodiment, blind vias 206 may be formed through the silicon handle wafer. Blind vias 206 may not extend completely through the wafer at this stage, but are advantageous in electrical connections once such layers are revealed. Additionally, trenches 208 may be formed at this operation to expose an area where the optical mode may exit the PIC and where a mirror or other such optical component might be inserted to direct the light into a fiber. Such trenching process may allow for future integration operations where the photonic and electronic components may be interconnected, but may also be formed in a later operation.

In FIG. 2B, wafer 200A may be wafer-to-wafer bonded to the photonic structure 100C (from FIG. 1C) and the silicon handle wafer may go through backside grind and polishing to reveal the blind vias. This process may be referred to as the TSV reveal process, during which, in some embodiments, approximately 600 microns of material may be removed from the backside of the wafer. The thinning process may be advantageous by revealing the through-silicon vias (TSVs), allowing for full metallization and electrical connections to be made through the structure. At this stage, the TSVs (through silicon vias) may be connected to the TDVs 116 from photonic structure 100C to create the full electrical link.

Once the TSVs are revealed, metallization may be applied to establish electrical connections between the photonic IC and possible EIC layers and the external systems. Such metallization may ensure that the blind vias, which were initially formed in the silicon handle wafer, may now serve as complete electrical pathways, connecting the backend metal stack to the base of the structure.

FIG. 2C demonstrates the next operation in the hybrid wafer-to-wafer bonding process of the embodiments herein, where the structure 200B is flipped onto a new Si carrier wafer 103 for support in the next process operation. After flipping onto a new support wafer, a trench 209 may be formed within the PIC 200C. Trench 209 may be carefully etched to provide space for further optical components, including lenses, reflectors and mirrors that are used for directing optical signals off the PIC. PIC 200C may enable larger modes to exit PIC 200C when compared to a standard silicon photonic design with a 2-3 micron BOX layer.

In FIG. 2D, PIC 200D may be further refined by the addition of an Electronic Integrated Circuit (EIC) 220, which may provide control over the photonic components. EIC 220 may be advantageous for managing the electrical signals that interact with the optical elements of the structure. The integration of the EIC 220 may create an optical engine, allowing the device to process both optical and electrical signals in a compact and efficient manner.

In some embodiments, a mirror 222 may also be introduced into PIC 200D structure, positioned within trench 209 formed earlier. Mirror 222, may be referred to as a Lower Body Reflector (LBR). LBR (e.g., mirror 222) may reflect optical signals within the photonic circuit vertically out of the PIC 200D. The inclusion of mirror 222 may be advantageous for improving the efficiency of optical signal transmission and ensuring that light is directed between waveguides and external fibers.

Mirror 222 may be positioned in the trench 209 to form a two-dimensional (2D) array as opposed to a linear array. Positioning the mirror in this manner may facilitate enhanced input/output when compared to a scenario in which a linear array is used.

In some embodiments, after the mirror 222 and EIC 220 are in place through die-to-wafer bonding techniques, PIC 200D may undergo further conformal oxide coating and thinning processes, reducing the overall thickness to approximately 10 to 40 microns. Such thinning process may ensure that the structure remains compact and flat for further wafer scale processing and integration while maintaining the mechanical and optical properties for high-performance applications.

At this stage, optional electrical connections 224, which may extend through the conformal oxide layers, may be fully connected to the backend metal stack 114. These electrical connections 224 above the PIC 200D, combined with routing layers in the backend metal stack 114, form a silicon bridge to electrically connect external ASICs to the optical engine for optical connectivity off-package. Thus, the electrical connections 224 may allow for the efficient transmission of electrical and optical signals across the device, which may be used for higher speed connectivity. This form factor may be used because it can allow for testing from the top side for both optical and electrical signals, improving throughput and test time for high volume usage.

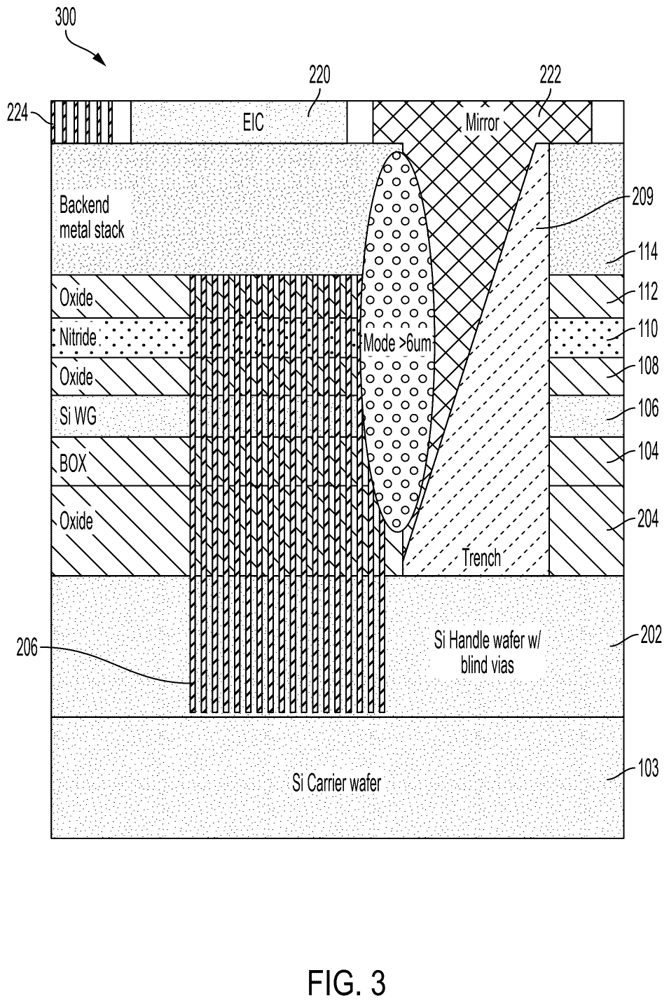

Referring now to FIG. 3 in conjunction with FIGS. 1-2, FIG. 3 depicts silicon photonic bridge (SPB) 300. SPB 300 may correspond to a silicon bridge (for electrical connectivity to external ASICs) embedded into an optical engine comprised of a PIC and EIC. In one embodiment, SPB 300 may include a PIC with an extended buried oxide layer. SPB 300 may correspond to a 3D integrated die stack which has undergone the hybrid wafer-to-wafer bonding process and chip-to-wafer bonding processes as described above. Accordingly, SPB 300 may encompass several advantages.

For example, by implementing the method described above, SPB 300 may include the ability to have a larger optical mode which may be greater than 6 microns. In SPB 300, by adding an additional oxide layer, the wafer-to-wafer bonding process of the embodiments herein may allow for a larger optical mode to propagate through the waveguide (e.g., Si WG 106 or nitride waveguide 110). Such larger mode may provide the advantage of looser alignment tolerances during manufacturing, resulting in improved optical coupling and overall performance.

The use of thicker oxide layers may enable the structure to support optical modes of varying sizes, in some embodiments, from less than 4 microns up to 15 microns, or in some embodiments, more than 15 microns, depending on the design. Such flexibility may allow for optimized performance in a variety of photonic applications. The ability to accommodate larger optical modes may reduce the use of precise alignment during the manufacturing process. This may result in improved yield and reduced costs, making the process advantageous for high-volume production.

The combination of TDVs, blind vias, and metallization may ensure efficient electrical connectivity throughout the structure. Meanwhile, the integration of mirrors and other optical components may enhance the optical performance, making the device well-suited for high-speed data transmission and processing applications.

Thus, SPB 300 may represent an advantageous process for integrating photonic and electronic components within a semiconductor device suitable for very high-speed applications. The use of TDVs, blind vias, trenches, and mirrors, and EIC, may create a high-performance system capable of processing both electrical and optical signals. The flexibility in mode size and the reduced alignment tolerances may make this process well-suited for next-generation photonic devices.

In addition or alternatively, oxide (e.g., oxide layer 204) may be deposited directly onto the PIC from FIG. 1C. The PIC may include one or more of a silicon carrier wafer 103, a backend metal stack 114, an oxide layer 112, a nitride layer 110, an oxide layer 108, a silicon waveguide 106, a BOX layer 104, or an oxide layer 204. The oxide layer 204 may have a thickness of from about 1 micron to about 10 microns.

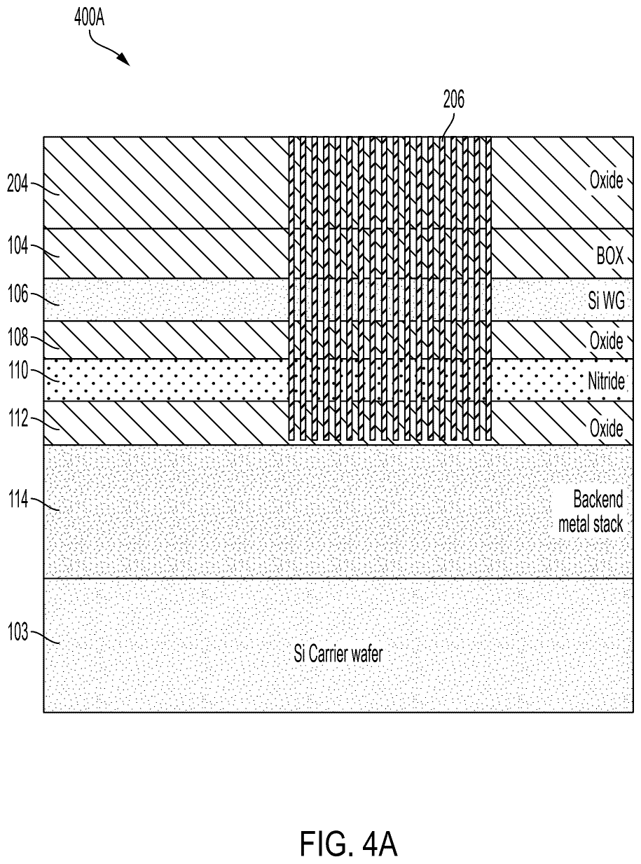

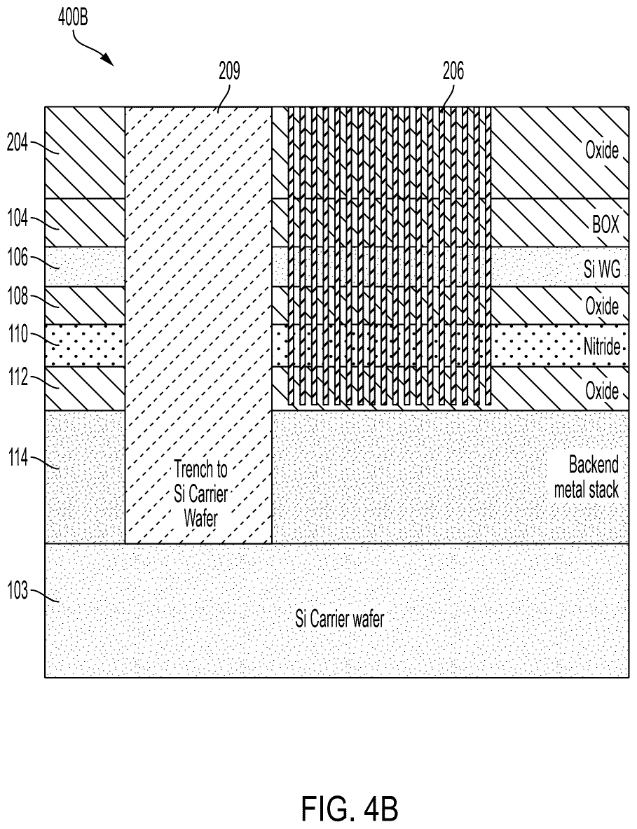

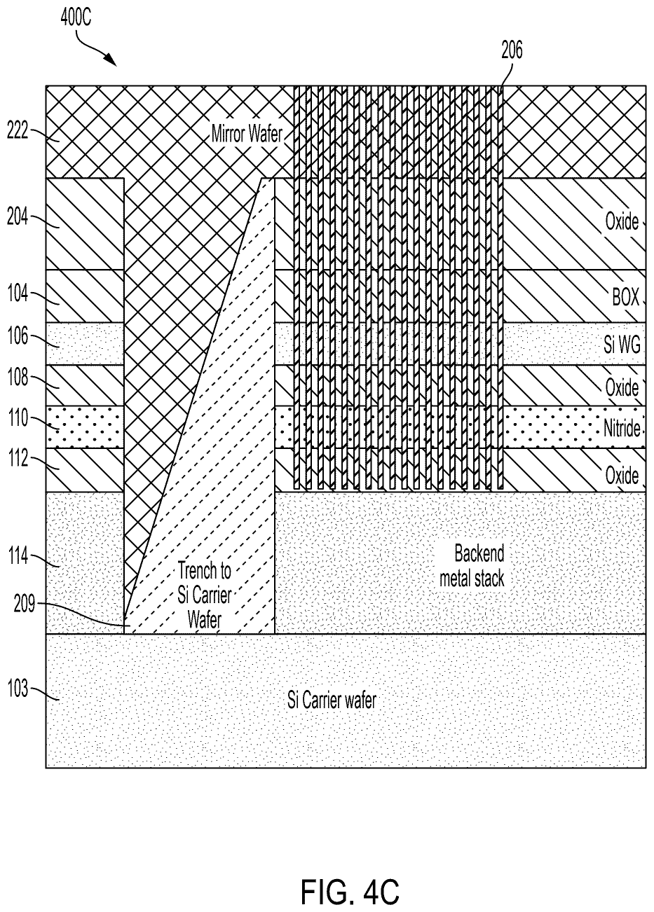

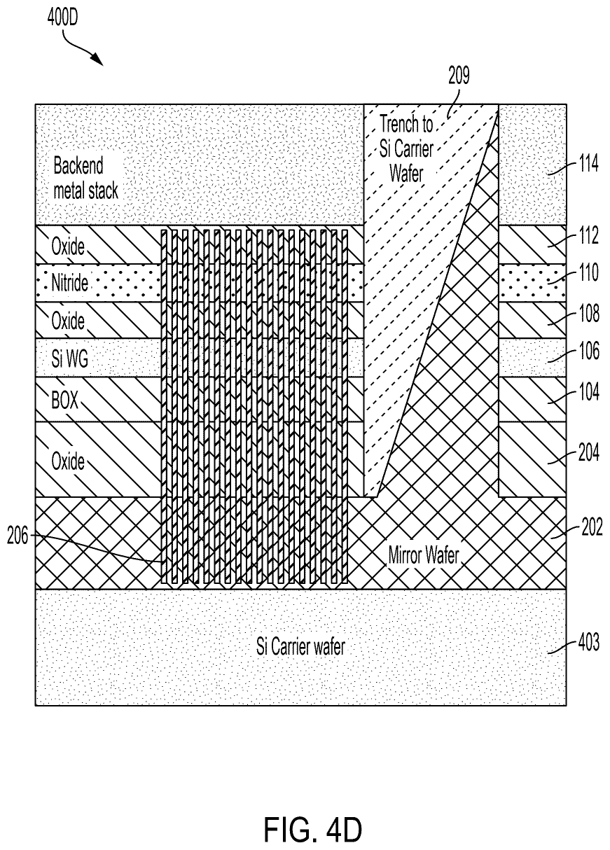

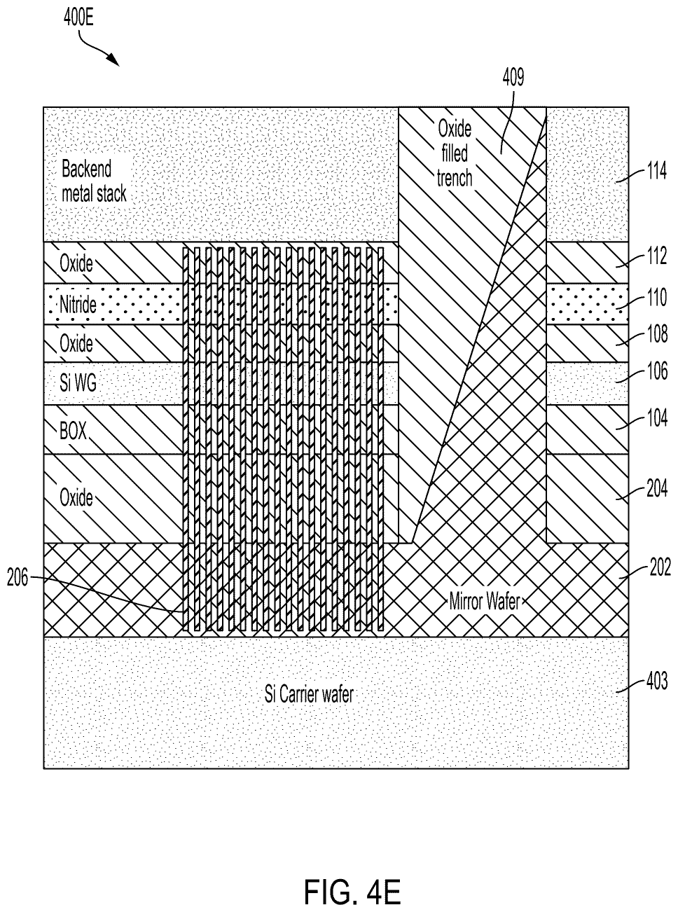

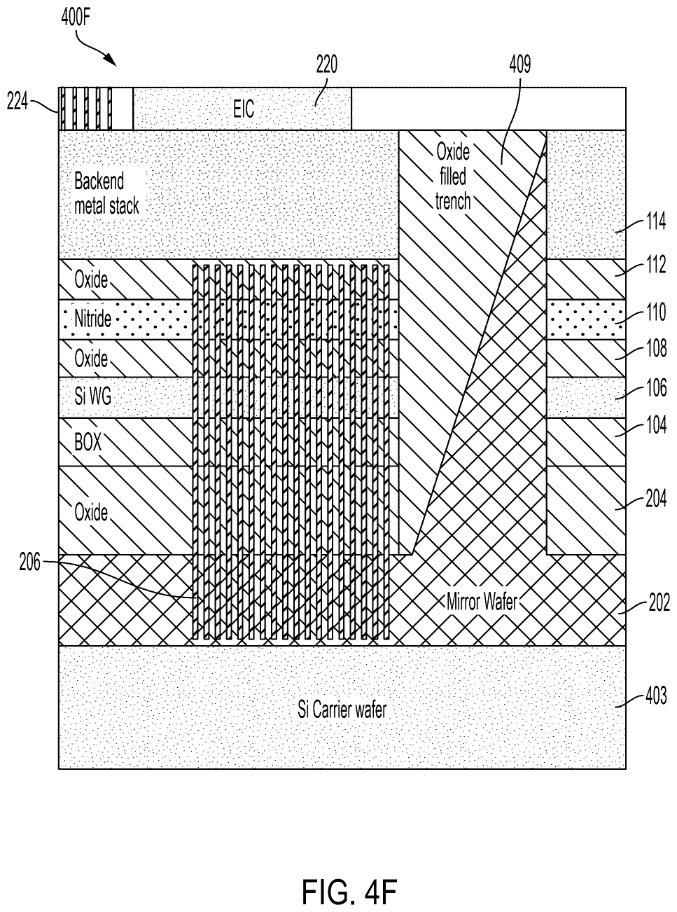

Through dielectric vias (TDVs) may be directly formed into this oxide layer 204 when an extended silicon thickness is not used. The TDVs 206 may extend through the oxide layer 112, the nitride layer 110, the oxide layer 108, the silicon waveguide 106, the BOX layer 104, and the oxide layer 204, as shown in FIG. 4A. The TDVs 206 may provide an electrical connection between the backend metal stack 114 and external components.

As illustrated in FIG. 4B, trench formation may happen from the oxide layer 204 through to the silicon carrier wafer 103 to facilitate placement of optical components from the backside (e.g., from the oxide layer 204). This build may allow wafer to wafer placement of optical components rather than die-to-wafer placement. For instance, turning mirrors (as shown in FIG. 4C) may be placed from the backside (e.g., from the oxide layer 204) but might not be placed from the topside (e.g., from the backend metal stack 114) during EIC integration.

As illustrated in FIG. 4C, wafer-to-wafer fusion and/or hybrid bonding may be used to position the mirror wafer 222. Vias 206, which may be TDVs or TSVs, may be formed before bonding or after bonding. The mirror wafer 222 may be thinned to a selected thickness (e.g., 1 to 100 microns) at this operation or a subsequent operation further downstream in the process.

As illustrated in FIG. 4D, once integrated, the PIC (e.g., layers 202, 204, 104 106, 108, 110, 112, 114) may be flipped onto another silicon carrier wafer 403 (for example if the original mirror wafer was thinned), removing the previous carrier wafer 103 to expose the trench 209 with embedded mirror 202.

As illustrated in FIG. 4E, the trench 209 with embedded mirror may be filled with oxide to form oxide filled trench 409 and planarized. Filling the trench with oxide and polishing the surface may prepare the PIC for hybrid bonding with an EIC.

As illustrated in FIG. 4F, at this point, the structure 400F may incorporate the hybrid bonding of the EIC 220, oxide deposition and planarization to the thickness of approximately 10-30 um followed by TDVs 224 to enable subsequent packaging integration for topside die-to-die (D2D) bonding with the ASIC as shown in FIG. 4F, which may be similar to FIG. 2D. In another embodiment, operation 4F may occur prior to operation 4A amongst other potential permutations.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter.

In the embodiments herein, the methods describe and/or semiconductor device 200, 300 components (e.g., 200A, 200B, 200C, 200D), 400 components (e.g., 400A, 400B, 400C, 400D, 400E, 400F) as part of or apart from the silicon photonic bridge may facilitate communication with a number of processing units (e.g., xPUs), switch ASICs, memory, or other similar ASICs requiring off-chip communication. One or more aspects or features of the subject matter described herein can be realized in digital electronic circuitry, integrated circuitry, specially designed ASICs, field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and may interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

Thus, the embodiments disclosed above provides a novel and efficient method for integrating photonic and electronic components within a semiconductor device, addressing limitations in existing packaging technologies. By incorporating through-dielectric vias (TDVs), blind vias, trenches, and the strategic placement of optical and electronic components, such as mirrors and electronic integrated circuits (EICs), the embodiments herein enhance both optical and electrical performance in a compact and scalable form.

The process described in the embodiments above allows for increased optical mode sizes, improving alignment tolerances and coupling efficiency, which may be advantageous for high-performance computing, telecommunications, and data transmission applications.

Accordingly, the embodiments described above may represent a significant advancement in semiconductor manufacturing by providing a flexible, scalable, and highly efficient platform for integrating photonic and electronic functionalities. The combination of these innovations may offer enhanced performance, reduced manufacturing complexity, and greater overall system reliability, making the embodiments herein an ideal solution for next-generation photonic-electronic devices.

The embodiments herein may provide the ability to test electrically and optically from the topside, which may be advantageous since most high-volume testers today only enable testing from one side. Enabling testing from two sides slows down the process and substantially increases the cost.

### EXAMPLES

Example 1 may include a method including a method, comprising: providing a silicon-on-insulator (SOI) wafer having a silicon handle wafer, a BOX layer, and a silicon waveguide layer; forming a photonic integrated circuit (PIC) including one or more of the waveguide or a metal layer; removing the silicon wafer to expose the BOX layer; and extending the BOX layer by one or more of: depositing oxide and planarizing onto the BOX layer to increase BOX layer thickness to an extended BOX layer, or fusion bonding a second wafer with a surface oxide layer.

Example 2 may include the method of Example 1, further comprising forming a trench through the PIC with the extended BOX to facilitate integration of optical components, wherein the trench is formed from one or more of a topside or a backside of the PIC.

Example 3 may include the method of Example 2, wherein the optical components comprise a mirror to redirect light vertically from the PIC, wherein the mirror is further integrated with fusion or hybrid bonding at a wafer level.

Example 4 may include the method of Example 3, further comprising: forming electrical vias including one or more of through dielectric vias (TDVs) or through silicon vias (TSVs) to connect a backside or a topside of the PIC to the metal layers, wherein the electrical vias extend through one or more layers including one or more of silicon, oxide, or nitride to connect with a backend metal stack; and wherein the electrical vias connect the backend metal stack to the surface to facilitate die-to-die connectivity to external components.

Example 5 may include the method of Example 3, wherein a remainder of the trench is filled with optically transparent material and planarized.

Example 6 may include the method of Example 1, further comprising bonding an electronic integrated circuit (EIC) to a top of a backend metal stack before trench formation or after trench formation.

Example 7 may include the method of Example 6, wherein the EIC is thinned and planarized with oxide deposition.

Example 8 may include the method of Example 1, further comprising placing an electronic integrated circuit (EIC) using hybrid bonding.

Example 9 may include the method of Example 1, further comprising one or more of oxide deposition, planarization, or electrical vias to facilitate communication from die-to-die.

Example 10 may include a device comprising: a photonic integrated circuit (PIC) comprising one or more of a waveguide layer positioned above a BOX layer, wherein the waveguide layer is operable to guide optical signals within the device; an additional oxide layer, positioned below the BOX layer, wherein the additional oxide layer facilitates an increase in BOX thickness beyond 2 μm to enable a larger optical mode when compared to a baseline optical mode; and an integrated optical component positioned to reflect or reshape optical signals within the waveguide layer vertically.

Example 11 may include the device of Example 10, wherein electrical vias are integrated to provide connectivity to one or more of a base or a top surface of the device.

Example 12 may include the device of Example 10, further comprising: a backend metal stack positioned above the waveguide layer, wherein the backend metal stack is operable to provide electrical connections for photonic and electronic components.

Example 13 may include the device of Example 12, further comprising: an electronic integrated circuit (EIC) positioned above the backend metal stack, wherein the EIC is operable to control photonic components within the device including one or more of modulation, routing, or amplification of optical signals.

Example 14 may include the device of Example 10, wherein positioned above or below the waveguide layer is an oxide layer and one or more of a nitride layer to enable optical mode expansion and beam shaping of greater than 4 microns and optical power greater than 25 milliwatts.

Example 15 may include the device of Example 10, wherein the BOX layer has a thickness of from about 2 microns to about 15 microns.

Example 16 may include the device of Example 10, wherein the integrated optical component is a mirror positioned within the PIC that is configured to align and couple optical signals between photonic components and external optical systems.

Example 17 may include the device of Example 10, wherein an electronic integrated circuit (EIC) is configured to interface with an external ASIC through electrical connections formed above a backend metal stack.

Example 18 may include the device of Example 10, further comprising one or more electrical vias that extend up to a total depth of approximately 775 microns from a backend metal stack to a silicon carrier wafer.

Example 19 may include the device of Example 10, further comprising a conformal oxide layer coating above a backend metal stack to facilitate vertical electrical connections to an external ASIC.

Example 20 may include the device of Example 10, wherein the integrated optical component is positioned to form a 2D array.

The embodiments described herein may be embodied in systems, apparatus, methods, computer programs and/or articles depending on the desired configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “embodiment” in the singular is not intended to imply any limitation on the scope of the claims set forth below. Multiple embodiments may be set forth according to the limitations of the multiple claims issuing from this disclosure, and such claims accordingly define the embodiment(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred embodiments, it is to be understood that such detail is solely for that purpose and that the disclosure is not limited to the expressly disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

1. A method, comprising:
providing a silicon-on-insulator (SOI) wafer having a silicon handle wafer, a buried oxide (BOX) layer, and a silicon waveguide layer;
forming a photonic integrated circuit (PIC) including one or more of the waveguide or a metal layer;
removing the silicon wafer to expose the BOX layer; and
extending the BOX layer by one or more of: depositing oxide and planarizing onto the BOX layer to increase BOX layer thickness to an extended BOX layer, or fusion bonding a second wafer with a surface oxide layer.

2. The method of claim 1, further comprising forming a trench through the PIC with the extended BOX to facilitate integration of optical components, wherein the trench is formed from one or more of a topside or a backside of the PIC.

3. The method of claim 2, wherein the optical components comprise a mirror to redirect light vertically from the PIC, wherein the mirror is further integrated with fusion or hybrid bonding at a wafer level.

4. The method of claim 3, further comprising:
forming electrical vias including one or more of through dielectric vias (TDVs) or through silicon vias (TSVs) to connect a backside or a topside of the PIC to the metal layers,
wherein the electrical vias extend through one or more layers including one or more
wherein the electrical vias connect the backend metal stack to the surface to facilitate die-to-die connectivity to external components.

5. The method of claim 3, wherein a remainder of the trench is filled with optically transparent material and planarized.

6. The method of claim 1, further comprising bonding an electronic integrated circuit (EIC) to a top of a backend metal stack before trench formation or after trench formation.

7. The method of claim 6, wherein the EIC is thinned and planarized with oxide deposition.

8. The method of claim 1, further comprising placing an electronic integrated circuit (EIC) using hybrid bonding.

9. The method of claim 1, further comprising one or more of oxide deposition, planarization, or electrical vias to facilitate communication from die-to-die.

10. A device comprising:
a photonic integrated circuit (PIC) comprising one or more of a waveguide layer positioned above a buried oxide layer (BOX) layer, wherein the waveguide layer is operable to guide optical signals within the device;
an additional oxide layer, positioned below the BOX layer, wherein the additional oxide layer facilitates an increase in BOX thickness beyond 2 μm to enable a larger optical mode when compared to a baseline optical mode; and
an integrated optical component positioned to reflect or reshape optical signals within the waveguide layer vertically.

11. The device of claim 10, wherein electrical vias are integrated to provide connectivity to one or more of a base or a top surface of the device.

12. The device of claim 10, further comprising:
a backend metal stack positioned above the waveguide layer, wherein the backend metal stack is operable to provide electrical connections for photonic and electronic components.

13. The device of claim 12, further comprising:
an electronic integrated circuit (EIC) positioned above the backend metal stack, wherein the EIC is operable to control photonic components within the device including one or more of modulation, routing, or amplification of optical signals.

14. The device of claim 10, wherein positioned above or below the waveguide layer is an oxide layer and one or more of a nitride layer to enable optical mode expansion and beam shaping of greater than 4 microns and optical power greater than 25 milliwatts.

15. The device of claim 10, wherein the BOX layer has a thickness of from about 2 microns to about 15 microns.

16. The device of claim 10, wherein the integrated optical component is a mirror positioned within the PIC that is configured to align and couple optical signals between photonic components and external optical systems.

17. The device of claim 10, wherein an electronic integrated circuit (EIC) is configured to interface with an external ASIC through electrical connections formed above a backend metal stack.

18. The device of claim 10, further comprising one or more electrical vias that extend up to a total depth of approximately 775 microns from a backend metal stack to a silicon carrier wafer.

19. The device of claim 10, further comprising a conformal oxide layer coating above a backend metal stack to facilitate vertical electrical connections to an external ASIC.

20. The device of claim 10, wherein the integrated optical component is positioned to form a 2D array.
